(19) United States
(12) Patent Application Publication
(10) Pub. No.: US 2005/0210346 A1
(43) Pub. Date: Sep. 22, 2005

(54) Closed loop dynamic power management

(76) Inventors: Alberto Comaschi, North Andover, MA (US); Tim Dodd, Westford, MA (US)

Correspondence Address: Matthew E. Connors;Gauthier & Connors LLP, Suite 3300, 225 Franklin Street, Boston, MA, 02110, US

(21) Appl. No.: 10/978,950

(22) Filed: Nov. 1, 2004

Related U.S. Application Data
(60) Provisional application No. 60/554,236, filed on Mar. 18, 2004.

(51) Int. Cl. G11C 5/00; G01R 31/28

(52) U.S. Cl. 714/724

(57) ABSTRACT

Closed loop dynamic power management is accomplished via a pass/fail detector executing test code in a chip to verify operation of the chip, and a voltage regulator working in a regulation loop with the pass/fail detector to regulate power by setting Vdd to a minimum allowable value for the chip. If the chip passes the test, power is regulated by decreasing Vdd and executing the test code until the chip fails to execute the test code. When the chip fails the test, Vdd is increased prior to being set as the minimum Vdd.

### RELATED APPLICATIONS

The present application claims the benefit of provisional patent application “Closed Loop Dynamic Power Management”, Ser. No. 60/554,236, filed Mar. 18, 2004.

### BACKGROUND OF THE INVENTION

The invention relates to the field of power management, and in particular to closed loop dynamic power management.

The goal of any power management scheme is to use the lowest possible power and still meet computational requirements by the processor. A characteristic of deep sub-micron CMOS processes is to have a large variation in power across the process corners. The power changes from part-to-part depending on the process, and it is common to have 40% variability in power. Conventional power management techniques are not optimized for this type of variation and are usually designed for the worst cases, such as process and environment.

Traditional power management schemes use look-up tables based on worst case process and environmental conditions. Although useful, deep submicron power variations are too large for this power management scheme to be effective.

Table 1, below, shows a traditional power management implementation that is based on a look-up table.

TABLE 1
Core and system clock requirements - ADSP-DM901

| Parameter | | Minimum | Maximum | Unit |
|---|---|---|---|---|
| t_{CCLK1.2} | Core Cycle Period | 1.67 | | ns |
| | (V_{DDINT} = 1.2 V − 5%) | | | |
| t_{CCLK1.1} | Core Cycle Period | 2.20 | | ns |
| | (V_{DDINT} = 1.1 V − 5%) | | | |
| t_{CCLK1.0} | Core Cycle Period | 2.40 | | ns |
| | (V_{DDINT} = 1.0 V − 5%) | | | |
| t_{CCLK0.9} | Core Cycle Period | 3.00 | | ns |
| | (V_{DDINT} = 0.9 V − 5%) | | | |
| t_{CCLK0.8} | Core Cycle Period | 3.20 | | ns |
| | (V_{DDINT} = 0.8 V) | | | |

| | | | |
|---|---|---|---|
| t_{SCLK} | System Clock Period | Maximum of (7.5 or | ns |
| | | t_{CCLKNN}) | |

In such power management implementations, the voltage is not tuned to a particular part, and such parts often run at higher voltages than needed to ensure the required processing performances. Hence, what is needed is a robust power management system wherein the supply voltage is tuned based on the required performances (such as clock rate) to ensure proper operations over process/environmental variation.

Whatever the precise merits, features, and advantages of such prior art power management systems, they fail to achieve or fulfill the purpose of the present invention.

### SUMMARY OF THE INVENTION

The present invention provides for a dynamic power management system and method. The closed loop dynamic power management system comprises a pass/fail detector executing test code in a chip to verify operation of the chip, and a voltage regulator working in a regulation loop with the pass/fail detector to regulate power by setting Vdd to a minimum value for the chip. If the chip passes the test, power is regulated by decreasing Vdd and executing the test code until the chip fails to execute the test code. When the chip fails the test, Vdd is increased prior to being set as the minimum required Vdd.

The present invention's closed loop dynamic power management method comprises the steps of: (a) setting maximum Vdd allowable for a chip; (b) executing a test code to verify if the chip passes a test; and (c) regulating power based on an iterative execution of the test code and reducing Vdd to a minimum allowable value, wherein, if the chip passes the test, power is regulated by decreasing Vdd and the test code is iterative executed until the chip fails to execute the test code; when upon such a failure, Vdd is increased prior to being set as the minimum allowable Vdd.

The present invention also provides for computer readable program code implementing the above-mentioned method for closed loop dynamic power management.

### BRIEF DESCRIPTION OF THE DRAWINGS

FIG. 1 illustrates a closed loop dynamic power management based on a “Pass/Fail” detector.

FIG. 2 illustrates a flow chart showing an exemplary method of the present invention.

FIGS. 3 and 4 illustrate charts showing a comparison of the present invention's control loop power management method and the look-up table based method of the prior art.

### DETAILED DESCRIPTION OF THE INVENTION

Although the present invention has been shown and described with respect to several preferred embodiments thereof, various changes, omissions and additions to the form and detail thereof, may be made therein, without departing from the spirit and scope of the invention.

The present invention provides for a robust power management system wherein the supply voltage is tuned based on the required performances (such as clock rate) to ensure proper operations over process/environmental variation. The disclosed technique provides for closed loop power control using the lowest possible power Vdd for each individual processor chip for a given MIPS requirement. The disclosed technique additionally adjusts to account for fabrication process and environmental conditions for the lowest possible power. Use of minimal allowable Vdd reduces both the switching current and leakage current.

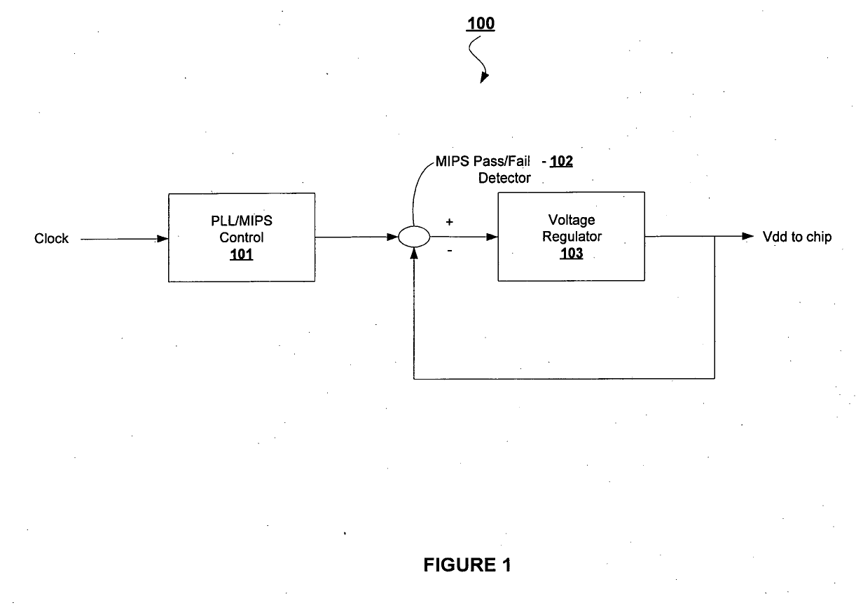

FIG. 1 illustrates an exemplary embodiment of the present invention's system 100. System 100 comprises a PLL/MIPS control unit 101, MIPS pass/fail detector 102, and voltage regulator 103. MIPS pass/fail detector 102 modulates voltage regulator 103 to minimum Vdd for individual chip and environmental conditions. For example, very fast process material would settle at a lower Vdd than a slow process product.

Using a fixed input clock, PLL/MIPS control 101 generates output clocks whose frequencies are user-programmable. PLL/MIPS output clocks are used to drive core and on-chip peripherals. Pass/fail detector 102 executes test code (e.g., a set of arithmetic and logic unit (ALU) operations or a set of instructions) in a chip to verify operation of the chip. Such test code execution operations (such as ALU operations) characterize the speed operation of a chip via parameters such as speed path, wherein the speed path is the time it takes to execute a code/operation in a chip.

Voltage regulator 103 works in a regulation loop with pass/fail detector 102 to regulate power based on an iterative execution of the test code and reducing Vdd to a minimum allowable value (for the chip). If the chip passes the test (by successfully executing the test code), power is regulated by decreasing Vdd and iteratively executing the test code until the chip fails to execute such code. For example, Vdd is decreased by one step in the device (ADI-BackFin) by about 50 mV. When the chip fails the test, Vdd is increased prior to being set as the minimum allowable Vdd. For example, Vdd is increased by one step in the device (ADI-BackFin) by about 50 mV.

System 100 of FIG. 1 tunes voltage to a specific part (e.g., chip) via setting a minimum operating voltage that ensures the required processing performance. By setting the Vdd to a minimum, both the switching current and the leakage current are reduced. Also, in such a system, the power-per-MIPs is constant from part-to-part (as such a setup is process independent).

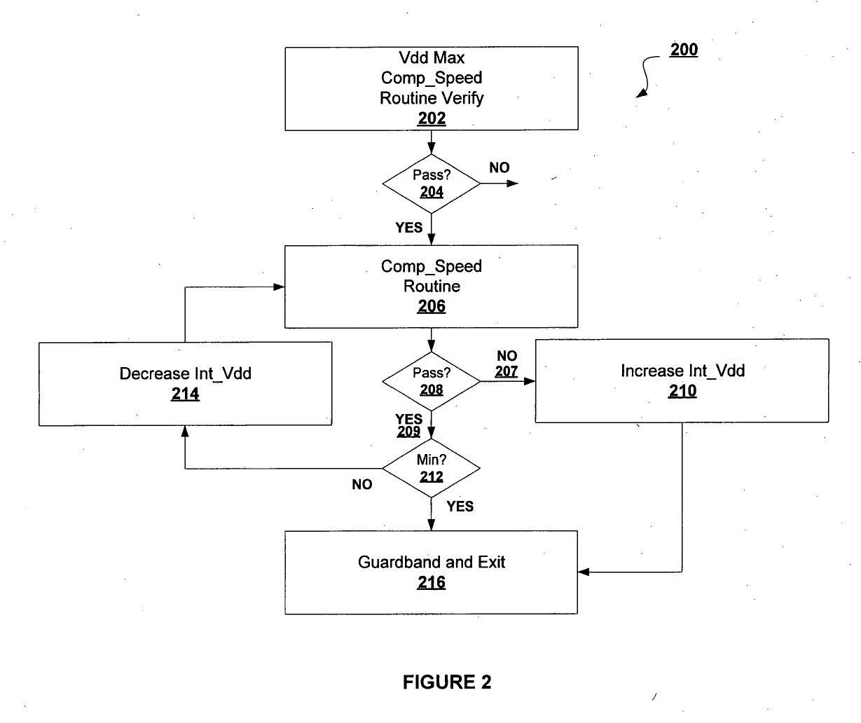

FIG. 2 illustrates an exemplary closed loop dynamic power management method 200 based on the present invention. In step 202, maximum allowable Vdd is set for a particular chip. Next, in step 204, a test code (e.g., a set of arithmetic and logic unit (ALU) operations or a set of instructions) is executed to verify if the chip passes (successfully executes) the test code. In the event, the chip fails to pass such a test, a non-recoverable error is recorded.

In steps 206-214, the code execution operation is performed in a loop and power is regulated based on the results of such execution by setting Vdd to a minimum. In step 208, a check is performed to see if the chip has successfully executed the test. If the chip passes the test (“Yes”—209), power is regulated by decreasing Vdd, as in step 214, and the test code is executed until the chip fails to execute the test code. Furthermore, a check is also performed in step 212 to see if the minimum voltage is for the actual frequency. When the chip fails the test (“No”—207), Vdd is increased in step 210 prior to being set as the minimum allowable Vdd. In step 216, if the minimum voltage for the actual frequency is reached or if Vdd was increased in step 210, a step 210, a guardband step is initiated and the process exits. The power management loop reaches a steady state once a given frequency is set (e.g., by the user) and at a given ambient temperature. The guarband step compensates for ambient temperature variations by increasing the Vdd value. The regulation loop can be disabled until a new frequency is set, for example, by the user.

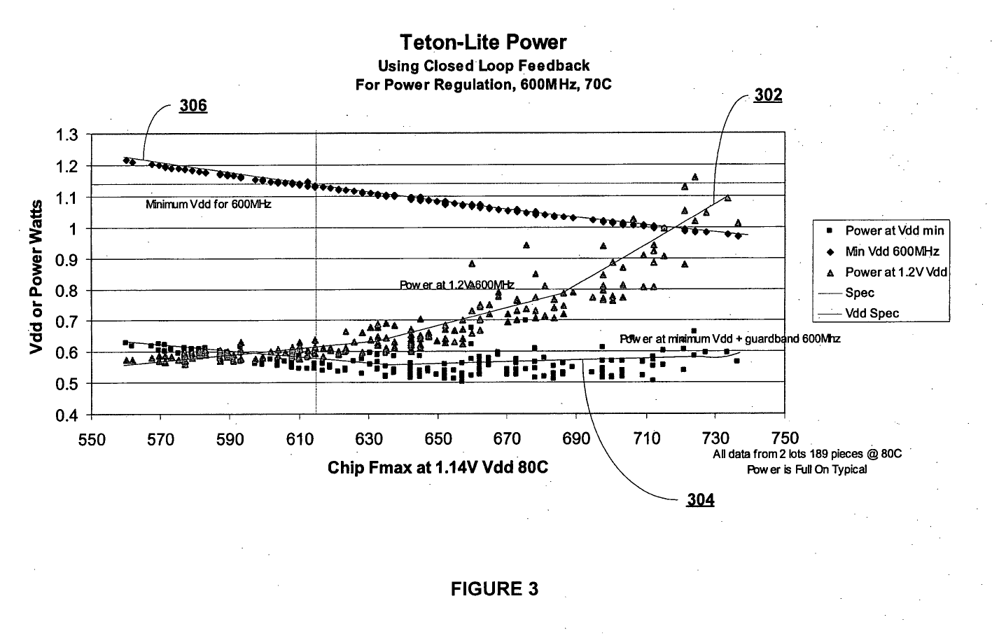

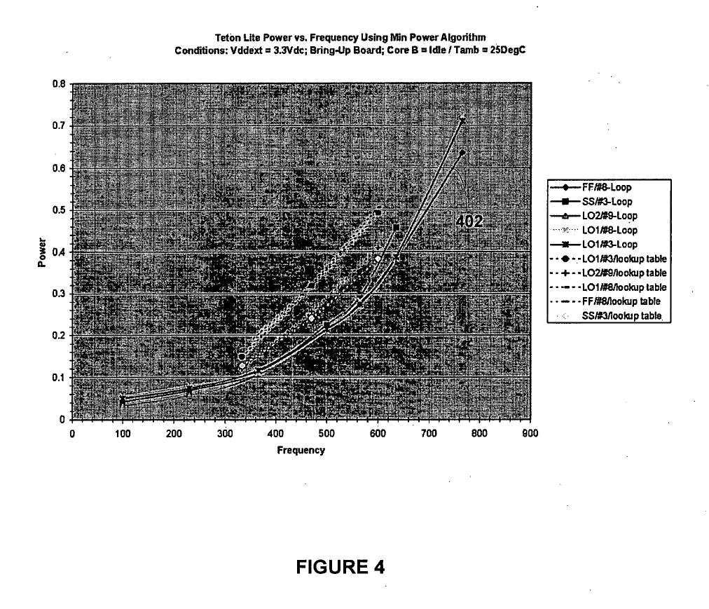

FIGS. 3 and 4 illustrate a chart showing a comparison of the present invention's control loop power management method and the look-up table method of the prior art. The results as shown in FIGS. 3 and 4 show as much as 50% power reduction with improved test yields.

The graphs of FIG. 3 represent a collection of data from 189 parts (many values are overlapped) from different production lots. On the left side of the chart are the samples from the slowest corner of the process; while at the right side of the chart are samples from the fastest corner of the process. Curve 306 represents the minimum value of Vdd needed for the part to fully operate at 600 MHz. Curve 302 represents the power consumption of the 189 samples using the traditional look-up table approach (in this case, the Vdd value is set to 1.2 volts for all the parts, to guarantee functionality at 600 MHz). Curve 302 shows that the parts from the fast corner of the process draw a higher power than parts from the slower corner of the process (operating at the same frequency/voltage).

Curve 304 represents the power consumption of the 189 samples using the closed-loop for for power regulation. The operating voltage in this case is determined by the PASS/FAIL detector. At a given operating frequency, the parts from the fastest process corner require a lower operating voltage (Vdd) while parts from the slowest corner of the process require a higher operating voltage (Vdd).

An advantage of the closed-loop power regulation method is the reduction in power consumption, in particular, for parts from fast and nominal process corner lots. Another advantage is that the poser consumption is predictable (constant) over process variations (it varies depending on the operating frequency, and consequently voltage), but is constant from part to part.

FIG. 4 illustrates a power versus frequency graph of various prior art look-up table approaches as compared against the closed loop approach of the present invention. The chart of FIG. 4 shows the power consumption (W) versus the core frequency (MHz) using both the closed-loop power regulation method (represented by solid curves) and traditional look-up table method (represented by dotted curves). As can be seen from curve 402, the present invention's control loop method provides for a more predictable, consistently lower power implementation as compared with other traditional approaches. The measurements are at ambient temperature and on several lots having different process skews (FF=Fast Fast, SS=Slow Slow, and LOT# indicates a random lot). For example, FF/#8 indicates the part labeled #8 from lot FF. As described earlier, some of the advantageous of the closed-loop method include, but are not limited to, reduced limited to, reduced power consumption and predictable/constant power consumption from part to part.

Furthermore, the present invention includes a computer program code based product, which is a storage medium having program code stored therein which can be used to instruct a computer to perform any of the methods associated with the present invention. The computer storage medium includes any of, but not limited to, the following: CD-ROM, DVD, magnetic tape, optical disc, hard drive, floppy disk, ferroelectric memory, flash memory, ferromagnetic memory, optical storage, charge coupled devices, magnetic or optical cards, smart cards, EEPROM, EPROM, RAM, ROM, DRAM, SRAM, SDRAM, and/or any other appropriate static or dynamic memory or data storage devices.

Implemented in computer program code based products are software modules for: setting maximum Vdd allowable for a chip; executing a test code to verify if the chip passes a test; and regulating power based on an iterative execution of the code and reducing Vdd to a minimum allowable value, wherein, if the chip passes the test, power is regulated by decreasing Vdd and executing the test code until the chip fails to execute the test code; when upon such a failure, Vdd is increased prior to being set as the minimum allowable Vdd.

1. A closed loop dynamic power management system comprising:
a pass/fail detector executing a test code in a chip to verify the chip passes a test; and
a voltage regulator working in a regulation loop with said pass/fail detector to regulate power by setting Vdd to a minimum allowable value for said chip.

2. A closed loop dynamic power management system, as per claim 1, wherein if said chip passes said test, power is regulated based on an iterative execution of the test code and reducing Vdd to a minimum allowable value, wherein, if by decreasing Vdd and executing said test code until said chip fails to execute said test code; and upon such failure, Vdd is increased prior to being set as the minimum Vdd value.

3. A closed loop dynamic power management system, as per claim 2, wherein Vdd is decreased if Vdd is less than the minimum voltage for a given frequency.

4. A closed loop dynamic power management method comprising:
setting maximum Vdd allowable for a chip;
executing a test code to verify if said chip passes said test; and
regulating power by iteratively executing said test code until said chip fails said test and setting Vdd to a minimum allowable value, wherein if said chip passes said test, power is regulated by reducing Vdd; and upon such failure, Vdd is increased prior to being set as the minimum allowable Vdd value.

5. A closed loop dynamic power management method, as per claim 4, wherein Vdd is decreased if Vdd is less than the minimum voltage for a given frequency.

6. An article of manufacture comprising a computer usable medium having computer readable program code embodied therein which implements a closed loop dynamic power management method, said medium comprising:
computer readable program code setting maximum Vdd allowable for a chip;
computer readable program code executing a test code to verify if said chip passes said test; and
computer readable program code regulating power by iteratively executing said test code until said chip fails said test and setting Vdd to a minimum allowable value, wherein if said chip passes said test, power is regulated by reducing Vdd; and upon such failure, Vdd is increased prior to being set as the minimum allowable Vdd value.

7. A closed loop dynamic power management system to reduce switching and leakage current comprising:
a PLL/MIPS control unit receives a clock rate as an input for setting core frequency;
a pass/fail detector executing test code in a chip to verify operation of said chip; and
a voltage regulator working in a regulation loop with said pass/fail detector to tune voltage supplied to a chip based on said clock rate to ensure proper operation over process and environmental variation by setting Vdd to a minimum allowable value for said chip.

8. A closed loop dynamic power management system as per claim 7, wherein if said chip passes said test, power is regulated based on an iterative execution of the test code and reducing Vdd to a minimum allowable value, wherein, if by decreasing Vdd and executing said test code until said chip fails to execute said test code; and upon such failure, Vdd is increased prior to being set as the minimum Vdd value.

9. A closed loop dynamic power management system, as per claim 8, wherein Vdd is decreased if Vdd is less than the minimum voltage for a given frequency.

10. An integrated circuit implemented a closed loop dynamic power management system to reduce switching and leakage current comprising:
a PLL/MIPS control circuit receiving a clock rate as an input for setting core frequency;
a pass/fail detector circuit executing test code in a chip to verify operation of said chip; and
a voltage regulator circuit working in a regulation loop with said pass/fail detector to tune voltage supplied to a chip based on said clock rate to ensure proper operation over process and environmental variation by setting Vdd to a minimum allowable value for said chip.

11. An integrated circuit as per claim 10, wherein if said chip passes said test, power is regulated based on an iterative execution of the test code and reducing Vdd to a minimum allowable value, wherein, if by decreasing Vdd and executing said test code until said chip fails to execute said test code; and upon such failure, Vdd is increased prior to being set as the minimum Vdd value.

12. An integrated circuit as per claim 10, wherein Vdd is decreased if Vdd is less than the minimum voltage for a given frequency.
